(19) United States
(12) Patent Application Publication
(10) Pub. No.: US 2010/0101727 A1
(43) Pub. Date: Apr. 29, 2010

(54) CAPACITIVELY COUPLED REMOTE PLASMA SOURCE WITH LARGE OPERATING PRESSURE RANGE

(76) Inventor: Helin Ji, Santa Clara, CA (US)

Correspondence Address: SCHNECK & SCHNECK, P.O. BOX 2-E, SAN JOSE, CA, 95109-0005, US

(21) Appl. No.: 12/606,745

(22) Filed: Oct. 27, 2009

Related U.S. Application Data
(60) Provisional application No. 61/108,809, filed on Oct. 27, 2008.

(51) Int. Cl. H01L 21/3065

(52) U.S. Cl. 156/345.29

(57) ABSTRACT

A radio frequency (RF) coaxial resonator feeding a saltshaker-like gas distributing electrode assembly forms a capacitively coupled plasma source. This apparatus can generate plasma of high density over a wide pressure range and large process window. The system may be used as a remote radical-rich plasma source for materials surface processing.

### CROSS-REFERENCE TO RELATED APPLICATION

This application claims priority under 35 U.S.C. 119(e) from U.S. provisional application 61/108,809 filed Oct. 27, 2008.

### TECHNICAL FIELD

The present invention relates generally to apparatus and methods for producing remotely radical-rich plasma for surface treatment including those of semiconductor devices, flat panel displays, thin film solar panels and polymers.

### BACKGROUND ART

Plasma containing reactive ions and free radicals has been widely used in material processing such as semiconductor wafers, flat panel displays and powders. In particular, the plasma generation is indispensable to the semiconductor manufacturing industry, including etching, photoresist stripping, Physical Vapor Deposition (PVD) and Plasma Enhanced Chemical Vapor Deposition (PECVD). Several methods have been proposed to generate plasma for these applications.

The most common one is the capacitive radio frequency (RF) discharge at the frequency of 13.56 MHz, commonly used in etch and deposition tools. This falls into the category of capacitively coupled plasma source. The typical design is one RF generator connected to one pair of plate electrodes within a vacuum enclosure containing a gas with selected pressure for a process. The RF generator is typically connected through an impedance matching network, which maintains constant RF power into the system and increase the coupling efficiency of generator power to the plasma. This type of plasma source generates plasma density low relative to the power used, due to the low frequency RF used.

Different modification have been used to extend this design such as employing a dual frequency version, Dual frequency systems generally allow one RF frequency source connected to one electrode to control plasma power and density while a 2^{nd} RF source connected to the other electrode, typically wafer side, to control the sheath potential, also referred to as wafer bias. This sheath potential is equal to the ion bombardment energy on the wafers.

Typical sheath potential is between 100 V and 1000 V for High Frequency (HF) RF sources. Such a high potential is good for highly anisotropic etching or deposition but it may cause damage to the structure on the wafer surface in certain application such as interlayer dielectric etching especially low-k oxide layer etching in sub-100 nm VLSI manufacturing. There is work to reduce this sheath potential by increasing the RF frequency applied to the upper electrode (U.S. Pat. No. 5,656,123, Salimian et al.). Use of a higher frequency RF range, VHF (very high frequency 30-300 MHz), also increases the plasma density.

Another type of plasma source used in the semiconductor industry is Inductively Coupled Plasma (ICP) including Transformer Coupled Plasma (TCP). They operate by coupling the RF energy from source to plasma inductively, i.e., through a coil, a solenoid or other inductive mechanism. This coupling mechanism has higher plasma density and lower sheath potential compared with capacitive plasma source at the same frequency and power. A bias RF power source may be applied to the lower wafer side electrode in order to control the sheath potential.

The limit of this type of plasma source is that the plasma density falls rapidly from the coupling coils because the magnetic field intensity decreases with increasing distances from coils. If the wafer is placed too close to the upper electrode, the coil structure may be seen. Large coil may have transmission line effects.

A microwave plasma source couples microwave energy into the gas chamber through a window or slot. A common microwave discharge is Electron Cyclotron Resonant (ECR) at 2.45 GHz. This type of source produces dense and low ion energy plasma, and therefore is often used as a remote plasma source for downstream processing. However this type of sources requires large magnetic field and an expensive microwave delivery system.

To address the need for plasma application for sensitive materials like the low-k dielectric on smaller feature 300 mm application or to minimize the energetic ion bombardment within the process chamber, there has been development on other remote plasma source. Toroidal plasma source (U.S. Pat. No. 6,150,628, Smith et al.) uses magnetically enhanced inductively coupling and a magnetic ferrite core wraps around RF coil and around a toroidal shaped chamber containing gas. An additional opening on this plasma chamber injects reactive ions and radical into a process chamber. This type of source still needs special plasma ignition mechanism and it lacks flexibilities in selective surface plasma processing. Ion shower grid type plasma process (U.S. Pat. Nos. 7,291,360 and 7,244,474, both to Hanawa et al.) is used to generate flux of ions from plasma so it is not suitable for sensitive materials surface treatment such as low-k dielectric layer etching.

### SUMMARY DISCLOSURE

The present invention is directed to a remote plasma source for materials surface processing. According to the present invention, apparatus and methods are provided for producing a plasma source made of mainly neutral radicals, as opposed to ions. The small kinetic energy of the radicals make this invention beneficial in the plasma processing of sensitive surface. This method achieves very high power coupling efficiency (>90%). With VHF driving RF power signal, this apparatus has very high plasma density (up to 10¹²/cm³ at about 1-5 kW RF source power).

This plasma source can self-ignite and can operate over a wide pressure range. The device of this invention is relatively simple to build and operate in comparison with ECR based remote plasma sources. Compared with toroidal plasma sources, the full structure can avoid the potential contamination because the electric fields that create the density are low by choice of the higher frequency. Furthermore, if additional protection from ion bombardment is needed, thin coatings of dielectric or conductors can be applied to the VHF structure with no damage to performance. On the other hand, the toroidal source nearly requires a high electric field in the gap to ignite the plasma. This necessitates low frequencies, and thus it intrinsically faces heavy ion bombardment at the dielectric boundary inside the toroidal source.

This apparatus consists of one VHF RF generator, a coaxial resonator, and one electrode head assembly enclosure containing gas(es). The VHF (30-300 MHz) RF generator drives one capacitor made of a pair of electrodes with spacing of 1 mm to 100 mm via the coaxial resonator. The lower electrode is perforated with gas distributing holes. RF source is directly taped into the coaxial resonator. The radicals flowing through the holes may be used for downstream processing of material surfaces. The holes may be shaped to minimize chamber arcing. Furthermore, the lower electrode may be shaped to assist in plasma uniformity above the holes. Of course, the distribution of the holes may be used to achieve desired spatial distribution of radicals on the treated surface below the source.

It is one objective of this invention to provide one remote plasma source for materials surface processing especially those sensitive to contamination that results from ion bombardment inside the remote source structure, which is typical in non-remote plasma source and some of remote source designs (U.S. Pat. No. 6,150,628, Smith et al.).

It is another objective to provide one remote plasma source without complicated RF matching network. Such matching network often adds up system cost and increases the system MTBF (mean time between failures). This can be achieved in several ways: 1) pre-tuned coaxial structure as in U.S. Pat. No. 5,656,123; 2) a conventional L-match pre-tuned and fixed to allow a partial match with no plasma to achieve plasma strike; or 3) an autotransformer self-resonant structure, again pre-tuned to allow strike. It shall be pointed out that such remote plasma source with impedance matching network is also covered by this invention.

One advantage of this apparatus is that the plasma in this system can self strike. This further reduces the system cost and makes the source easy to use and operate.

The direct guiding of the plasma out of metal electrode allows flexible design in radical distributing pattern for selective area applications like wafer edge or materials walls.

### BRIEF DESCRIPTION OF THE DRAWINGS

FIG. 1 is azimuthal view of the remote plasma source in accordance with one embodiment of the invention. The remote source is shown integrated in one processing chamber for material surface processing.

FIG. 2 is an embodiment of this apparatus for edge or sidewall processing.

FIG. 3 is one embodiment showing the gas can be introduced into the system in different pattern.

### DETAILED DESCRIPTION

With reference to FIG. 1, a remote plasma source 10 is driven by RF source 12 and integrated into a process chamber such as a semiconductor wafer-processing chamber. RF VHF source 12 is connected to the RF matchbox 9. The plasma entering the machine chamber from remote source 10 will react with materials 13 on pedestal 14.

The inner conductor 6 of coax cable from match box 9 is connected to one electrode 1. The outer conductor 7 of the coaxial cable forms one enclosure 2 around inner electrode 1, and they are insulated with dielectric ring 3. Enclosure 2 is situated on chamber 11. The enclosure 2 is connected to the output of one RF matchbox and the RF generator is connected to input of the matchbox. The internal elements are tuned to partially match to strike, yet provide a decent match when plasma is on.

The additional pump port 5 is to help maintain the vacuum level in the remote source lower than the vacuum level in the machine chamber, into which the remote plasma source is integrated. Port 4 feeds gas(es) into this plasma source and pass between the capacitive plates. The bottom plate 8 of enclosure 2 is perforated with gas holes. Holes of different size (from ½″ to 1/64″, 12.7 mm to 400 μm, in diameter), pattern and distribution can vary depending on the gases, materials surface to be processed, pressure and other factors. The electrodes could be made of aluminum and anodized at the surfaces exposed to plasma. The dielectric ring 3 can be ceramic such as alumina or quartz.

The enclosure 2 is grounded so the plasma ions and electrons are stopped at bottom plate 8. The radicals and gas molecules escape into the machine chamber through those gas-distributing holes in bottom plate 8. These radicals and gas molecules can diffuse to the surface of material 13 and reacts to lead to designed effects. The electric field within the pair of capacitor plates 1 and 8 drives and maintain plasma identical to traditional capacitively coupled plasma design in semiconductor wafer processing chambers. The use of plate 8 to generate plasma independent of materials 13 and its pedestal 14 as well as adding radical leaking holes in plate 8 is the essence of the invention.

The shape of bottom 8 and the gas distributing hole pattern can be altered based on the applications. Different embodiments are all part of this invention. The shapes of those holes can be circular, oval or other variations including different beveling at the hole edges. The hole distribution in plate 8 can be uniform over the processing wafers or non-uniform to process specific area on material 14. When uniform holes are distributed on the lower electrode 8, the remote plasma effect will be larger at the center of the surface of the processed material 13. Furthermore, the shape of either electrode can be made to be “convex” or “concave” to assist in achieving plasma uniformity inside the chamber. For instance, when the lower electrode 8 is shaped so that the spacing between the electrodes 1 and 8 is smaller at the center, the RF energy, and hence the plasma, will be more concentrated at the center.

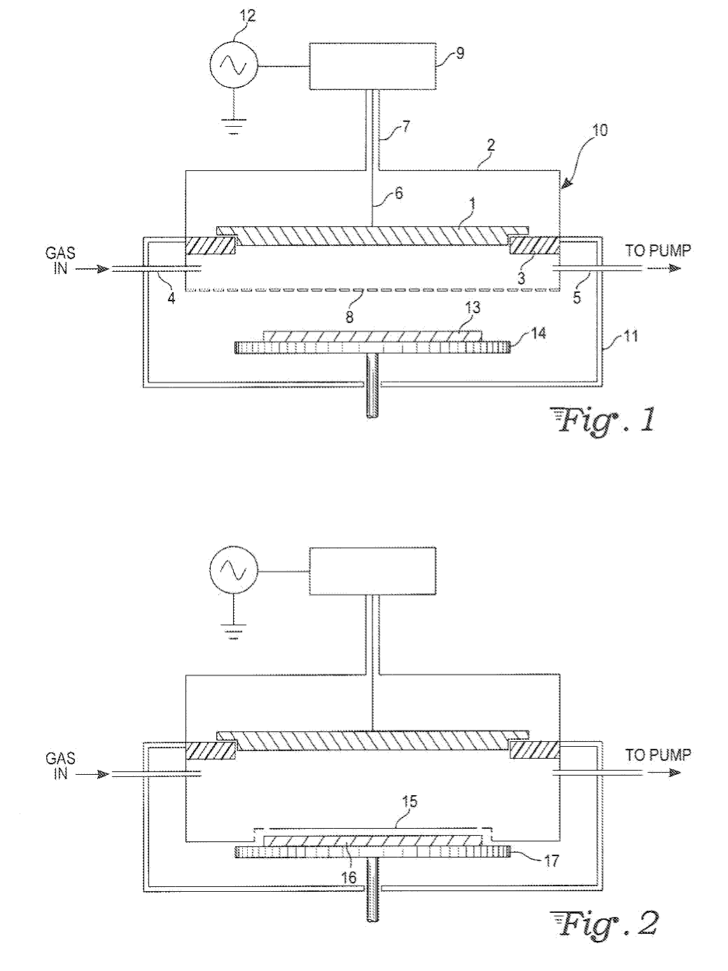

FIG. 2 shows one embodiment of this invention where the plate 15 is designed to leak radicals close to the edges of material 16 only. Such embodiment can be used to clean polymer at the edge of wafers after low k oxide etching step in VLSI manufacturing.

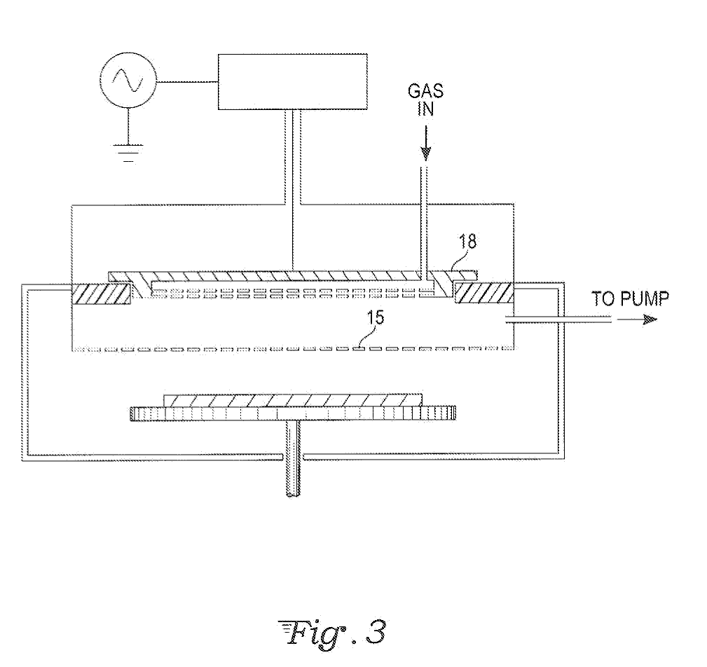

FIG. 3 shows one embodiment in that the gases are fed into remote source via showerhead 18. Such a design would lead to more uniform radical from electrode 19 to the underneath materials to be processed, which is necessary for certain applications.

Another embodiment is that a bias RF is connected to the pedestal to generate conventional capacitively coupled plasma in the processing chamber. The combination of this plasma with radicals from remote plasma source could generate beneficial results not available otherwise.

Advantages of the present invention include:

1) The plasma source generates flux of mainly radicals, which makes it suitable for surface treatment of sensitive materials, unlike most other remote plasma sources.
2) Besides the acting area flexibility of such remote plasma source, the electrode can be shaped to conform to flat surface or round to treat films on rolls or shaped to treat cylinder wall or wafer edge.
3) This capacitive remote plasma source has ultra wide pressure window source (3-10,000 mT, ≈400 mPa-1333 Pa), which enables new radicals not feasible with ICP remote plasma source (U.S. Pat. No. 6,150,628, Smith et al.).
4) It has such a low electrical field with sheath potential of tens of volts or even smaller. It can be placed very close to the surface to be treated. This enables new radicals otherwise infeasible for long-plasma-to-target-path ICP source. Due to low electrical field, such a remote plasma source can be long life and this makes it compatible with many materials as liner in the process chambers.
5) Due to metal nature such a remote plasma source allows pure dielectric or semiconducting liner, thus a low particle-generation and low contamination source.

What is claimed is:

1. An apparatus forming a remote plasma source for materials processing, comprising:
a pair of capacitive electrodes with a lower electrode of the pair perforated with holes such that charge-neutral radicals leaking through the holes can process materials placed below the lower electrode; and
a power source applying one RF voltage to an upper electrode of the pair, the lower electrode being grounded to the same potential as material being processed.

2. The apparatus as in claim 1, wherein the holes in the lower electrode have a distribution and density selected so as to control a uniformity profile of the charge-neutral radicals leaking to the material being processed.

3. The apparatus as in claim 1, wherein at least one of the pair of capacitive electrodes has a shape designed to obtain a desired uniformity profile of plasma between the electrodes.

4. An apparatus as in claim 3, wherein the shape of the lower electrode is planar so as to conform to a flat surface of the material being processed.

5. An apparatus as in claim 3, wherein the shape of the lower electrode is cylindrically curved so as to conform cylinder surface of the material being processed.

6. An apparatus as in claim 1, wherein the power source has RF amplitude that produces an electric field with a sheath potential of only tens of volts.

7. An apparatus as in claim 1, wherein the pair of capacitive electrodes form a plasma chamber with an ultra wide pressure window ranging from 3 mT to 10,000 mT.
